(19) United States
(12) Patent Application Publication
(10) Pub. No.: US 2026/0173764 A1
(43) Pub. Date: Jun. 18, 2026

(54) ELECTRONIC DEVICE AND METHOD FOR FABRICATING THE SAME

(71) Applicant: SK hynix Inc., Gyeonggi-do (KR)

(72) Inventors: Dae Hee LEE, Gyeonggi-do (KR); Eun Kyo BYUN, Gyeonggi-do (KR); Bo Kyung JUNG, Gyeonggi-do (KR)

(21) Appl. No.: 19/243,014

(22) Filed: Jun. 19, 2025

(30) Foreign Application Priority Data
Dec. 18, 2024 (KR) 10-2024-0189437

(51) Int. Cl. H10N 50/01; H10B 61/00; H10N 50/10

(52) U.S. Cl. CPC H10N 50/01; H10B 61/10; H10N 50/10

(57) ABSTRACT

Disclosed are an electronic device and a method for fabricating the same. The electronic device includes: a semiconductor memory that includes at least one stacked structure. Each stacked structure includes an electrode pattern; a magnetic tunnel junction (MTJ) pattern formed over the electrode pattern; a hard mask pattern formed over the MTJ pattern; a first spacer formed on both sidewalls of the electrode pattern; and a sacrificial layer pattern formed over at least a portion of the first spacer and supporting the MTJ pattern and the hard mask pattern.

### CROSS-REFERENCE TO RELATED APPLICATIONS

The present application claims priority under 35 U.S.C 119(a) to Korean Patent Application No. 10-2024-0189437, filed on Dec. 18, 2024, which is incorporated herein by reference in its entirety.

### BACKGROUND

### 1. Field

Various embodiments of the present disclosure relate to a semiconductor technology, and more particularly, to a semiconductor device including a Magnetic Tunnel Junction (MTJ), and a method for fabricating the semiconductor device.

### 2. Description of Related Art

Recent demands for miniaturization, low power consumption, high performance, and diversification of electronic devices require semiconductor devices capable of storing data in diverse electronic devices, such as computers, portable communication devices and the like. Researchers and the industry are studying to develop semiconductor devices that fulfill these requirements. Semiconductor devices that are being developed and investigated for these purposes include those capable of storing data by using the characteristics of switching between different resistance states according to the applied voltage or current, such as a Resistive Random Access Memory (RRAM), a Phase-change Random Access Memory (PRAM), a Ferroelectric Random Access Memory (FRAM), a Magnetic Random Access Memory (MRAM), an E-fuse and the like.

### SUMMARY

Embodiments of the present disclosure are directed to an electronic device that may secure the reliability and performance of a Magnetic Tunnel Junction (MTJ) element by effectively removing a MTJ etching byproduct, and a method for fabricating the same.

In accordance with an embodiment of the present disclosure, an electronic device includes: a semiconductor memory including at least one stacked structure, wherein each of the at least one stacked structure includes: an electrode pattern; a magnetic tunnel junction (MTJ) patterns formed over the electrode patterns; a hard mask pattern formed over the MTJ pattern; a first spacer formed on both sidewalls of the electrode pattern; and a sacrificial layer pattern formed over at least a portion of the first spacer and supporting the MTJ pattern and the hard mask pattern.

In accordance with another embodiment of the present disclosure, a method for fabricating a semiconductor device includes: forming a magnetic tunnel junction (MTJ) layer over a sacrificial layer having an electrode pattern buried therein; forming a hard mask layer over the MTJ layer; forming an MTJ pattern and a hard mask pattern by etching the MTJ layer and the hard mask layer, where an etching byproduct of the MTJ layer is accumulated on an upper surface of the sacrificial layer; removing the etching byproduct while removing the sacrificial layer.

### BRIEF DESCRIPTION OF THE DRAWINGS

FIGS. 1A to 1C are cross-sectional views illustrating a semiconductor device and a method for fabricating the same according to a comparative example.

FIGS. 2A to 2D are cross-sectional views illustrating a semiconductor device and a method for fabricating the same in accordance with an embodiment of the present disclosure.

FIGS. 3A to 3D are cross-sectional views illustrating a semiconductor device and a method for fabricating the same in accordance with another embodiment of the present disclosure.

### DETAILED DESCRIPTION

Hereinafter, the various embodiments of the present disclosure will be described in detail with reference to the attached drawings.

Various embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

Before describing the embodiments of the present disclosure, a comparative example and the problems thereof for comparison with the embodiments of the present disclosure will be described first.

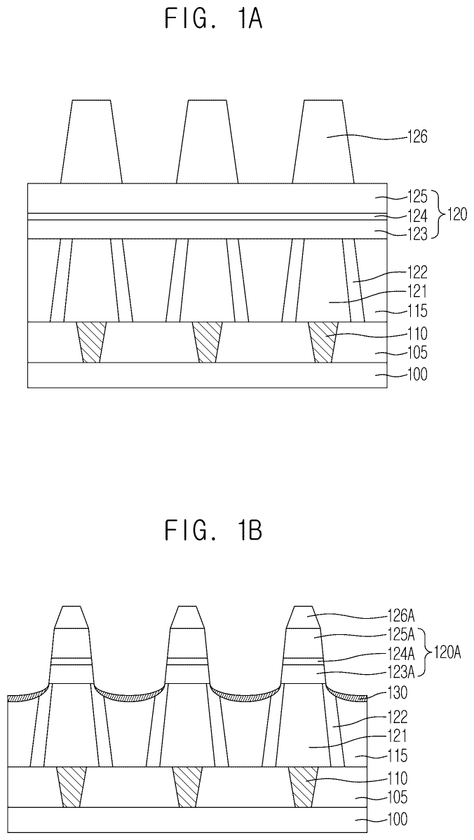

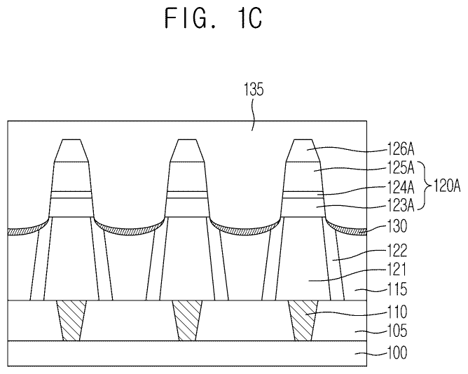

FIGS. 1A to 1C are cross-sectional views illustrating a semiconductor device and a method for fabricating the same according to a comparative example.

Referring to FIG. 1A, a first inter-layer dielectric layer 105 may be formed over a substrate 100.

Subsequently, the first inter-layer dielectric layer 105 may be selectively etched to form a hole that exposes a portion of the substrate 100, and then a lower contact plug 110 may be formed to fill the lower portion of the hole.

Subsequently, a lower electrode layer may be formed over the lower contact plug 110. Subsequently, a hard mask layer may be formed over the lower electrode layer, and then a lower electrode pattern 121 may be formed by using the hard mask layer as an etching barrier and patterning the lower electrode layer into a pillar shape. The hard mask layer may include a dielectric material, polysilicon (Poly-Si), or a combination thereof, and the hard mask layer may have a single-layer structure or a multi-layer structure. The dielectric material may include an oxide, a nitride, or a combination thereof. For example, the hard mask layer may include a dielectric material selected from the group including silicon oxide, silicon nitride, silicon carbide, aluminum oxide, hafnium oxide, titanium oxide, and zirconium oxide. The lower electrode pattern 121 may be a portion of a variable resistance element and may be distinguished from the lower contact plug 110 that is coupled to the lower end of the variable resistance element to couple the variable resistance element to another element. After the lower electrode pattern 121 is formed, a dielectric material for a spacer may be deposited onto the lower electrode pattern 121 and the first inter-layer dielectric layer 105 by a method such as Chemical Vapor Deposition (CVD), Atomic Layer Deposition (ALD), or the like. A spacer 122 may be formed by performing an isotropic dry etching process to remove the dielectric material from the upper portion of the first inter-layer dielectric layer 105 and leaving the dielectric material only on the sidewall of the lower electrode pattern 121. Only the dielectric material on the sidewall of the lower electrode pattern 121 may remain by performing a selective etching process in the vertical direction through a Reactive Ion Etching (RIE) process.

After the lower electrode pattern 121 and the spacer 122 are formed, a sacrificial layer 115 may be formed to fill the space between the lower electrode patterns 121. The sacrificial layer 115 may include a dielectric material, polysilicon (Poly-Si), or a combination thereof, and the sacrificial layer 115 may be formed as a single-layer structure or a multi-layer structure. An oxide, a nitride, or a combination thereof may be used as the dielectric material. For example, the sacrificial layer 115 may include SiO₂, SiN₄, SiOCN, SiON, polysilicon (Poly-Si), or a combination thereof. Subsequently, after the upper surfaces of the sacrificial layer 115 and the lower electrode pattern 121 are planarized, a Magnetic Tunnel Junction (MTJ) layer 120 may be formed on the upper surfaces of the sacrificial layer 115 and the lower electrode pattern 121. According to this comparative example, the MTJ layer 120 may include a free layer 123, a tunnel barrier layer 124, and a fixed layer 125 that are sequentially stacked therein. Subsequently, a hard mask layer 126 may be formed over the fixed layer 125 of the MTJ layer 120.

Referring to FIG. 1B, the MTJ layer 120 including the free layer 123, the tunnel barrier layer 124, and the fixed layer 125 may be patterned into a pillar shape by using the hard mask layer 126 as an etching barrier. The hard mask layer 126 may include a dielectric material, polysilicon (Poly-Si), or a combination thereof, and the hard mask layer 126 may have a single-layer structure or a multi-layer structure. The dielectric material may include an oxide, a nitride, or a combination thereof. For example, the hard mask layer 126 may include a dielectric material selected from the group including silicon oxide, silicon nitride, silicon carbide, aluminum oxide, hafnium oxide, titanium oxide, and zirconium oxide.

Through this patterning, an MTJ pattern 120A including a free layer pattern 123A, a tunnel barrier layer pattern 124A, and a fixed layer pattern 125A, and a hard mask pattern 126A may be formed in a pillar shape. In this instance, an MTJ etching byproduct 130 may accumulate on the upper surfaces of the sacrificial layer 115 and the spacer 122. The accumulated MTJ etching byproduct 130 may form an electrical bridge between the lower electrode patterns 121. This bridge may cause an electrical short between the electrodes, which may interfere with a normal operation of the MTJ element and result in a malfunction. The MTJ etching byproduct 130 may be mainly formed of a metal with a low reactivity, and consequently it may be difficult to remove the MTJ etching byproduct 130 by a general reactive ion etching (RIE) process or a wet cleaning (CLN) process. Therefore, it is required to develop a technology for effectively removing the MTJ etching byproduct 130.

Referring to FIG. 1C, a second inter-layer dielectric layer 135 may be formed over the structure of FIG. 1B. The second inter-layer dielectric layer 135 may include a dielectric material, polysilicon (Poly-Si), or a combination thereof, and the second inter-layer dielectric layer 135 may be formed as a single-layer structure or a multi-layer structure. An oxide, a nitride, or a combination thereof may be used as the dielectric material.

The MTJ etching byproduct 130 generated in the general MTJ patterning process as illustrated in the comparative example may be accumulated on the upper surfaces of the sacrificial layer 115 and the spacer 122, and the MTJ etching byproduct 130 may not be easily removed. Additionally, the MTJ etching byproduct 130 may affect the uniformity of the second inter-layer dielectric layer 135 formed thereon (and on the upper surfaces of the sacrificial layer 115), thereby deteriorating the performance of the subsequent process. Due to the incomplete removal of the MTJ etching byproduct 130, the inter-layer insulation performance may be deteriorated, and ultimately, the MTJ etching byproduct 130 may also have a negative influence on the electrical characteristics of the MTJ element. Furthermore, when the MTJ etching byproduct 130 remains, this may adversely affect the magnetoresistance characteristics of the MTJ element to decrease the reliability of the MTJ element.

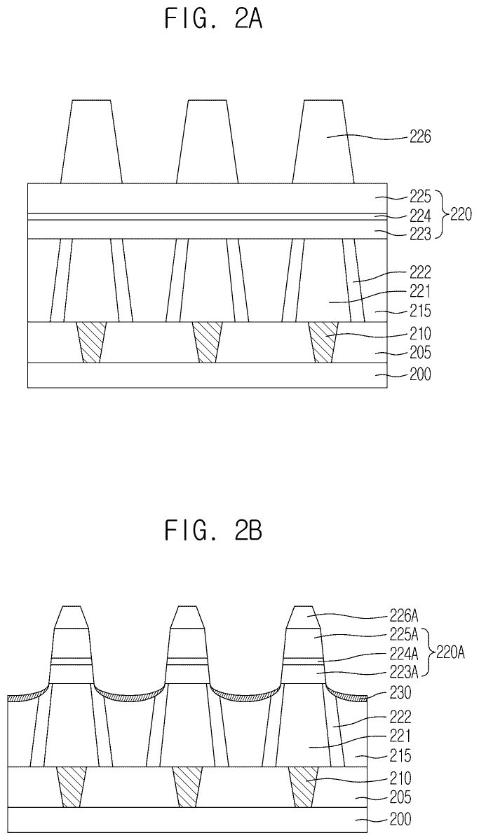

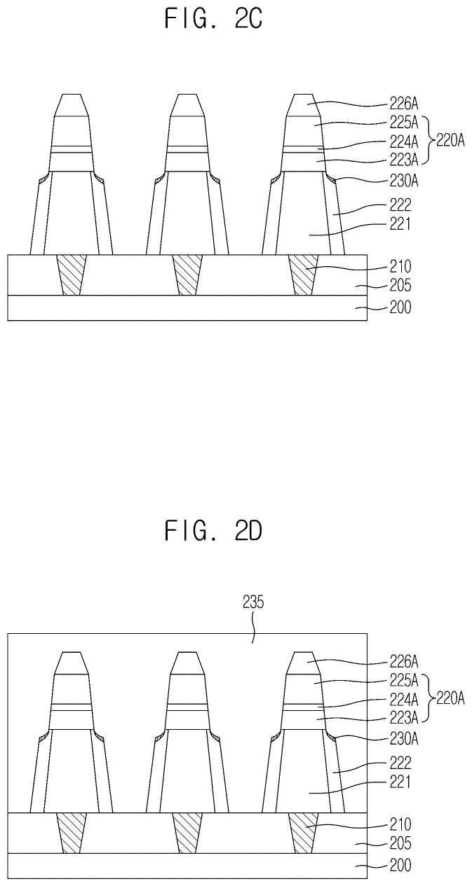

In order to solve the concerns of the semiconductor device according to the above described comparative example, a semiconductor device and a method for fabricating the same in accordance with an embodiment of the present disclosure may provide a method for effectively removing the MTJ etching byproduct 130 by forming a sacrificial layer of a material having an etching selectivity with respect to the hard mask layer and, removing the sacrificial layer and the MTJ etching byproduct together. Detailed description on the present disclosure will be provided below by referring to FIGS. 2A to 2D.

FIGS. 2A to 2D are cross-sectional views illustrating a semiconductor device and a method for fabricating the same in accordance with an embodiment of the present disclosure.

Referring to FIG. 2A, a substrate 200 including a required predetermined structure, for example, a switching element (not shown) and the like, formed therein may be provided. In this instance, the switching element may be coupled to a variable resistance element to control supply of a current or voltage to the variable resistance element, and the switching element may include, for example, a transistor, a diode and the like. One end of the switching element may be electrically connected to a lower contact plug 210, which will be described herein below, and the other end of the switching element may be electrically connected to an interconnection (not shown), such as a source line.

Subsequently, a first inter-layer dielectric layer 205 may be formed over the substrate 200. The first inter-layer dielectric layer 205 may include diverse dielectric materials, such as silicon oxide, silicon nitride, or a combination thereof.

Subsequently, the first inter-layer dielectric layer 205 may be selectively etched to form a hole that exposes a portion of the substrate 200, and thereafter a lower contact plug 210 may be formed to fill the lower portion of the hole. The lower contact plug 210 may be formed by selectively etching the first inter-layer dielectric layer 205 to form a contact hole that exposes a portion of the substrate 200, depositing a conductive material to have a thickness which is sufficiently thick to fill the contact hole, and performing a planarization process, such as Chemical Mechanical Polishing (CMP), until the upper surface of the first inter-layer dielectric layer 205 is exposed. The lower contact plug 210 may include a conductive material having excellent filling characteristics and high electrical conductivity. The lower contact plug 210 may include, for example, a metal such as tungsten (W), tantalum (Ta) and the like, or a metal nitride such as titanium nitride (TiN) and the like.

Subsequently, a lower electrode layer may be formed over the lower contact plug 210. Subsequently, a lower electrode pattern 221 may be formed by forming a hard mask layer over the lower electrode layer, and patterning the lower electrode layer into a pillar shape with the hard mask layer used as an etching barrier. The lower electrode pattern 221 may be a portion of the variable resistance element. The lower electrode pattern 221 may be distinguished from the lower contact plug 210 that is coupled to the lower end of the variable resistance element to couple the variable resistance element with another element. The lower electrode pattern 221 may include tungsten (W), titanium nitride (TiN), tantalum (Ta), molybdenum (Mo), or copper (Cu).

After the lower electrode pattern 221 is formed, a dielectric material for forming a spacer may be deposited onto the lower electrode pattern 221 and the first inter-layer dielectric layer 205 by a method such as Chemical Vapor Deposition (CVD), Atomic Layer Deposition (ALD), or the like. A spacer 222 may be formed by performing an isotropic dry etching process to remove the dielectric material from the upper portion of the first inter-layer dielectric layer 205 and leaving the dielectric material only on the sidewall(s) of the lower electrode pattern 221. A selective etching process may be performed in the vertical direction through a Reactive Ion Etching (RIE) process until only the dielectric material on the sidewall of the lower electrode pattern 221 remains. The spacer 222 may mainly contain carbon and the spacer 222 may have a dielectric property. Additionally or alternatively, the spacer 222 may further contain a small amount of a metal or an oxide of the metal, compared to the amount of carbon in the spacer 222. The metal may be a metal included in the lower electrode pattern 221, but according to an alternative embodiment of the process, a metal included in the MTJ pattern 220A shown in FIG. 2B may be additionally contained. The oxide of the metal may have a dielectric property. For example, the spacer 222 may include silicon oxide, silicon nitride, hafnium oxide, tantalum oxide, tantalum nitride, titanium nitride, aluminum oxide, or a combination thereof.

According to an embodiment of the present disclosure, since the lower contact plug 210 is formed in a hole in the first inter-layer dielectric layer 205 and the lower electrode pattern 221 is formed in another hole in the sacrificial layer 215, the sidewalls of the lower contact plug 210 and the lower electrode pattern 221 may not be aligned with each other. However, according to another embodiment of the present disclosure, the lower contact plug 210 and the lower electrode pattern 221 may have sidewalls that are aligned with each other.

According to an embodiment of the present disclosure, the lower electrode pattern 221 may have a width which is greater than that of the lower contact plug 210 while overlapping with the lower contact plug 210. However, according to another embodiment of the present disclosure, the position and width of the lower electrode pattern 221 may vary only when the lower electrode pattern 221 is coupled to the lower contact plug 210.

After the lower electrode pattern 221 and the spacer 222 are formed, a sacrificial layer 215 may be formed to fill the space between the spacers 222 against the lower electrode patterns 221. The sacrificial layer 215 may be formed of a material having an etching selectivity with respect to the hard mask layer 226. The hard mask layer 226 may be formed of a dielectric material, and the dielectric material may include silicon oxide, aluminum oxide, hafnium oxide, silicon nitride, aluminum nitride, or silicon oxynitride, which may be used to form a dielectric layer of the hard mask layer 226. The sacrificial layer 215 may be formed of a material including carbon, such as amorphous carbon, diamond-like carbon (DLC), graphite, carbon-containing polyimide, or parylene-C, in consideration of the etching selectivity with respect to the hard mask layer 226.

Subsequently, after the upper surfaces of the sacrificial layer 215 and the lower electrode pattern 221 are planarized, a Magnetic Tunnel Junction (MTJ) layer 220 may be formed on the upper surfaces of the sacrificial layer 215 and the lower electrode pattern 221. According to an embodiment of the present disclosure, the MTJ layer 220 may include a free layer 223, a tunnel barrier layer 224, and a fixed layer 225 that are sequentially stacked. In some embodiments, in order to form an MTJ structure, the free layer 223 has a changeable magnetization direction, the fixed layer 225 has a fixed magnetization direction, and the tunnel barrier layer 224 is interposed between the free layer 223 and the fixed layer 225, which allows tunneling of electrons when necessary, for example, during a data write operation that changes the resistance state of the variable resistance element. Each of the free layer 223 and the fixed layer 225 may have a single-layer structure or a multi-layer structure including a ferromagnetic material. The ferromagnetic material may include an alloy containing iron (Fe), nickel (Ni) or cobalt (Co) as a main component, such as an iron-platinum (Fe—Pt) alloy, an iron-palladium (Fe—Pd) alloy, a cobalt-iron (Co—Fe) alloy, a cobalt-palladium (Co—Pd) alloy, a cobalt-platinum (Co—Pt) alloy, a cobalt-iron-nickel (Co—Fe—Ni) alloy, an iron-nickel-platinum (Fe—Ni—Pt) alloy, a cobalt-iron-platinum (Co—Fe—Pt) alloy, a cobalt-nickel-platinum (Co—Ni—Pt) alloy, a cobalt-iron-boron (Co—Fe—B) alloy and the like, or a stacked structure such as cobalt/platinum (Co/Pt), cobalt/palladium (Co/Pd) and the like. The positions of the free layer 223 and the fixed layer 225 may be switched with each other with the tunnel barrier layer 224 interposed therebetween. In other words, the free layer 223 may be disposed over the tunnel barrier layer 224, and the fixed layer 225 may be disposed below the tunnel barrier layer 224 and over the lower electrode pattern 221. The tunnel barrier layer 224 may have a single-layer structure or a multi-layer structure including, for example, a metal oxide such as magnesium oxide (MgO), calcium oxide (CaO), strontium oxide (SrO), titanium oxide (TiO), vanadium oxide (VO), niobium oxide (NbO) and the like. Subsequently, a hard mask layer 226 may be formed over the fixed layer 225 of the MTJ layer 220. The hard mask layer 226 may include a dielectric material, polysilicon (Poly-Si), or a combination thereof, and the hard mask layer 226 may have a single-layer structure or a multi-layer structure. The dielectric material may include an oxide, a nitride, or a combination thereof. For example, the hard mask layer 226 may include a dielectric material selected from the group including silicon oxide, silicon nitride, silicon carbide, aluminum oxide, hafnium oxide, titanium oxide, and zirconium oxide.

Referring to FIG. 2B, the MTJ layer 220 including the free layer 223, the tunnel barrier layer 224, and the fixed layer 225 may be patterned into a pillar shape by using the hard mask layer 226 as an etching barrier. The etching process may be performed by a process applying strong physical etching characteristics, such as an ion beam etching (IBE) process. Accordingly, the resulting stacked structure may have a shape whose width increases from the top of the structure to the (base or) bottom of the structure. The upper portion of the lower electrode pattern 221 may have a sidewall aligned with the MTJ pattern 220A, but the lower portion of the lower electrode pattern 221 may not. The hard mask pattern 226A may be removed during the etching process or through a separate removal process. Additionally, when the hard mask pattern 226A includes a conductive material, a portion of the hard mask pattern 226A may remain (i.e., a hard mask patterned feature with the remnant of the hard mask pattern 226A incorporated into the device).

Through the patterning process, a stacked structure in which the pillar-shaped MTJ pattern 220A including the free layer pattern 223A, the tunnel barrier layer pattern 224A, and the fixed layer pattern 225A, and the hard mask pattern 226A are stacked may be formed. In these instances, an MTJ etching byproduct 230 may accumulate on the upper surfaces of the sacrificial layer 215 and the spacer 222. The MTJ etching byproduct 230 may form an electrical bridge between the lower electrode pattern 221. The lower electrode pattern 221 may include an upper portion having a sidewall aligned with the MTJ pattern 220A, and a lower portion having a sidewall that is not aligned with the upper portion while having a width which is greater than that of the upper portion.

Referring to FIG. 2C, the MTJ etching byproduct 230 may be removed together with the sacrificial layer 215. The sacrificial layer 215 may be a layer that is designed to be removed together with the MTJ etching byproduct 230, and a dry etching process or a plasma etching process may be performed to remove the sacrificial layer 215. Since the sacrificial layer 215 is formed of a material having an etching selectivity with respect to the hard mask pattern 226A, when the sacrificial layer 215 is etched, only the sacrificial layer 215 and the MTJ etching byproduct 230 accumulated thereon may be selectively removed without damaging the MTJ pattern 220A.

In the dry etching process, oxygen plasma or fluorine-based plasma may be used, which is effective in selectively removing the carbon-based sacrificial layer 215. Fine byproducts that may remain after the dry etching process may be removed through a wet cleaning process. The wet cleaning process may be a process of removing the residues or byproducts remaining on the surface by using a chemical solution, and an acidic or alkaline solution may be used. Through this process, the MTJ etching byproduct 230 may be effectively removed, and the surface of the stacked structure may be cleaned. Since the surface may be prepared for a subsequent process by removing the sacrificial layer 215 and the MTJ etching byproduct 230, the embodiments of the present disclosure provide a capability to prevent deterioration in the performance of the formation of an inter-layer dielectric layer or other processes, and to ensure electrical reliability.

Most of the sacrificial layer 215 may be removed but a portion of the sacrificial layer 215 may remain, and accordingly a sacrificial layer pattern (not shown) may be formed over at least a portion of the spacer 222. The sacrificial layer pattern may structurally support the MTJ pattern 220A and the hard mask pattern 226A. This supporting role may contribute to maintaining the physical stability of the MTJ pattern 220A, especially after the pattern is formed. The MTJ pattern 220A may have a fine (for example, fragile) structure and may be easily damaged during an etching process or a subsequent process. However, since the sacrificial layer pattern physically supports the MTJ pattern 220A, the MTJ pattern 220A may be prevented from being deformed, broken down, or otherwise damaged. Also, the sacrificial layer pattern may alleviate the thermal and mechanical stresses that may occur during a subsequent process. When the sacrificial layer pattern remains over the spacer 222, the physical bonding between the spacer and the MTJ pattern may be further enhanced. In this way, the sacrificial layer pattern may serve as an important element that provides not only the function of being removable (during device formation) but also enhances the stability of the patterned structure and ensures the performance and reliability of the device. The sacrificial layer pattern may be formed of a material containing carbon, such as amorphous carbon, diamond-like carbon (DLC), graphite, carbon-containing polyimide, or parylene-C, similar to the composition of the sacrificial layer 215. Also, the sacrificial layer pattern may further include polysilicon, silicon oxide, silicon nitride, aluminum oxide, or titanium oxide.

Referring to FIG. 2D, a second inter-layer dielectric layer 235 may be formed over the structure of FIG. 2C. The second inter-layer dielectric layer 235 may be formed of a dielectric material, polysilicon (Poly-Si), or a combination thereof. The second inter-layer dielectric layer 235 may be formed as a single layer structure or a multi-layer structure. An oxide, a nitride, or a combination thereof may be used as the dielectric material, and the dielectric material may include, for example, silicon oxide, silicon nitride, silicon oxynitride, silicon oxide carbonitride, or a combination thereof. Since the surface of the structure of FIG. 2C is cleaned by a dry etching process and a wet cleaning process, the quality of the bonding between the second inter-layer dielectric layer 235 and the surface of the structure of FIG. 2C may be improved.

A semiconductor device as illustrated in FIG. 2D may be formed by the process described above.

Referring back to FIG. 2D, the semiconductor device in accordance with the embodiment of the present disclosure may include the lower contact plug 210 disposed over the substrate 200 and coupled to a portion of the substrate 200, the first inter-layer dielectric layer 205 filling the space between the lower contact plugs 210, the lower electrode pattern 221 coupled to the lower contact plug 210 over the lower contact plug 210, the spacer 222 formed on a sidewall of the lower electrode pattern 221, the MTJ pattern 220A coupled to the lower electrode pattern 221 over the lower electrode pattern 221, the hard mask pattern 226A formed over the MTJ pattern 220A, and the second inter-layer dielectric layer 235 covering the upper surfaces of the spacer 222, the MTJ pattern 220A, and the hard mask pattern 226A.

The spacer 222 may mainly contain carbon and may have a dielectric property. Also, the spacer 222 may further include a small amount of a metal (or metalloid, such as silicon) or an oxide of the metal, compared to the amount of carbon in the spacer 222. The spacer 222 may alternatively contain a nitride. The metal may be a metal included in the lower electrode pattern 221, and may further include a metal included in the MTJ pattern 220A according to the particular process. The oxide (or nitride) of the metal (or metalloid) may have a dielectric property. For example, the spacer 222 may include silicon oxide, silicon nitride, hafnium oxide, tantalum oxide, tantalum nitride, titanium nitride, aluminum oxide, or a combination thereof.

The MTJ pattern 220A may store data by switching between different resistance states according to the voltage or current applied to the lower and upper portions of the MTJ pattern 220A. To be more specific, the MTJ pattern 220A may store data in such a manner that is contrasted with the magnetization direction of the fixed layer pattern 225A by varying the magnetization direction of the free layer pattern 223A according to the voltage or current applied to the MTJ pattern 220A. When the magnetization directions of the free layer pattern 223A and the fixed layer pattern 225A are parallel to each other, the MTJ pattern 220A may be in a low resistance state and the MTJ pattern 220A may store, for example, data ‘1’. Conversely, when the magnetization directions of the free layer pattern 223A and the fixed layer pattern 225A are anti-parallel to each other, the MTJ pattern 220A may be in a high resistance state and the MTJ pattern 220A may store, for example, data ‘0’. The magnetization direction of the free layer pattern 223A may be changed due to spin transfer torque. The magnetization directions of the free layer pattern 223A and the fixed layer pattern 225A may be perpendicular to the interface of the layers, for example, the interface between the free layer pattern 223A and the tunnel barrier layer pattern 224A.

According to the semiconductor device and the method for fabricating the same described above, the embodiments effectively remove the MTJ etching byproduct 230 to prevent deterioration of the magnetoresistance characteristics of the MTJ element and the reliability of the MTJ element and prevent deterioration of the performance of inter-layer insulation and the electrical characteristics of the MTJ element. Also, the sacrificial layer pattern may structurally support the MTJ pattern 220A and contribute to maintaining the physical stability of the MTJ pattern 220A.

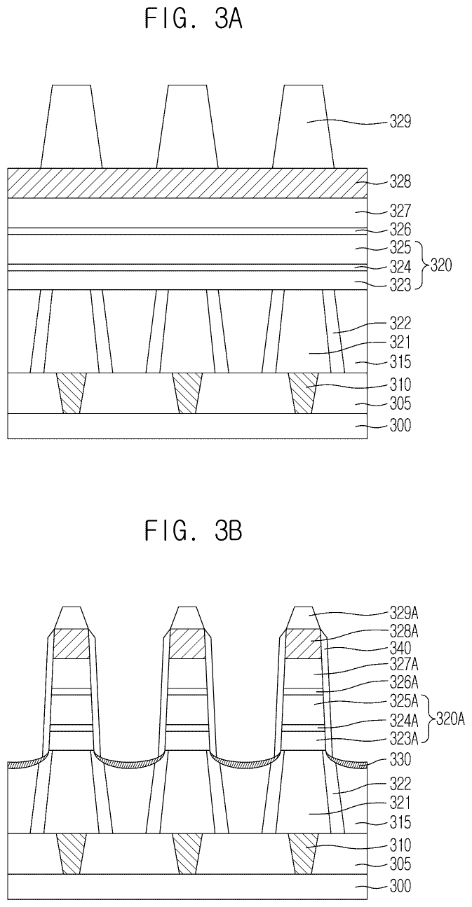

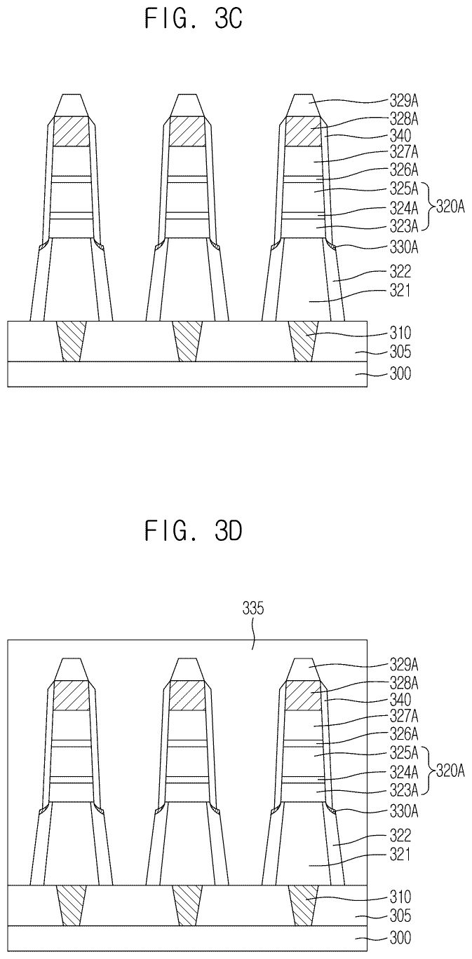

Further, according to embodiments of the present disclosure, the stacked structure may include the MTJ pattern 220A and the hard mask pattern 226A, but other embodiments of the present disclosure may also be possible. For example, the stacked structure may further include any of (or combination of) an exchange bonding layer pattern, a magnetic compensation layer pattern, and a capping layer pattern over the MTJ pattern 220A, and may further include a second spacer on a sidewall of the stacked structure. This embodiment is described below with reference to FIGS. 3A to 3D.

FIGS. 3A to 3D are cross-sectional views illustrating a semiconductor device and a method for fabricating the same in accordance with another embodiment of the present disclosure. Detailed description of aspects substantially the same as those described with respect to the above-described embodiment of the present disclosure will be omitted.

Referring to FIG. 3A, a substrate 300 including a required predetermined structure, such as a switching element (not shown), formed therein may be provided. One end of the switching element may be electrically connected to a lower contact plug 310 described below, and the other end of the switching element may be electrically connected to an interconnection (not shown) such as a source line.

Subsequently, a first inter-layer dielectric layer 305 may be formed over the substrate 300. Subsequently, a lower contact plug 310 that penetrates the first inter-layer dielectric layer 305 to be coupled to a portion of the substrate 300, for example, one end of the switching element, may be formed.

Subsequently, a lower electrode layer may be formed over the lower contact plug 310. Subsequently, a lower electrode pattern 321 may be formed by forming a hard mask layer over the lower electrode layer and patterning the lower electrode layer into a pillar shape with the hard mask layer used as an etching barrier. After the lower electrode pattern 321 is formed, a dielectric material for forming a spacer may be deposited over the lower electrode pattern 321 and the first inter-layer dielectric layer 305 by a method such as chemical vapor deposition (CVD), atomic layer deposition (ALD), and the like. An isotropic dry etching process may be performed to remove the dielectric material from the upper portion of the first inter-layer dielectric layer 305, and a spacer 322 may be formed by leaving the dielectric material only on the sidewall of the lower electrode pattern 321. After the lower electrode pattern 321 and the spacer 322 are formed, a sacrificial layer 315 may be formed to fill the space between the lower electrode pattern 321. The sacrificial layer 315 may be formed of a material containing carbon, such as amorphous carbon, diamond-like carbon (DLC), graphite, carbon-containing polyimide, or parylene-C, in consideration of the etching selectivity with respect to the hard mask layer 326.

Subsequently, the upper surfaces of the sacrificial layer 315 and the lower electrode pattern 321 may be planarized, and then an MTJ layer 320 may be formed on the upper surfaces of the sacrificial layer 315 and the lower electrode pattern 321. According to an embodiment of the present disclosure, the MTJ layer 320 may include a free layer 323, a tunnel barrier layer 324, and a fixed layer 325 that are sequentially stacked.

Additionally, a variable resistance element including an exchange bonding layer 326, a magnetic compensation layer 327, and a capping layer 328 may be formed by further stacking the exchange bonding layer 326, the magnetic compensation layer 327, and the capping layer 328 over the MTJ layer 320. The magnetic compensation layer 327 may offset or reduce (for example, eliminate or partially reduce) the influence of a stray magnetic field that is generated by the fixed layer 325 over the fixed layer 325. To this end, the magnetic compensation layer 327 may have a magnetization direction which is opposite to that of the fixed layer 325. The exchange bonding layer 326 may be interposed between the fixed layer 325 and the magnetic compensation layer 327 to provide an exchange bond between the fixed layer 325 and the magnetic compensation layer 327. The capping layer 328 may be disposed at the top portion of the variable resistance element and may function as a hard mask during the patterning of the variable resistance element, which is described below, while also functioning as an upper electrode of the variable resistance element.

Subsequently, a hard mask layer 329 for patterning the stacked structure may be formed over the capping layer 328.

Referring to FIG. 3B, a stacked structure of an MTJ pattern 320A including a capping layer pattern 328A, a magnetic compensation layer pattern 327A, an exchange bonding layer pattern 326A, a fixed layer pattern 325A, a tunnel barrier layer pattern 324A, and a free layer pattern 323A may be formed by etching the capping layer 328, the magnetic compensation layer 327, the exchange bonding layer 326, the fixed layer 325, the tunnel barrier layer 324, and the free layer 323 with the hard mask layer 329 used as an etching barrier.

As a result, a variable resistance element including the lower electrode pattern 321, the capping layer pattern 328A, the magnetic compensation layer pattern 327A, the exchange bonding layer pattern 326A, the fixed layer pattern 325A, the tunnel barrier layer pattern 324A, and the free layer pattern 323A that are stacked therein may be formed.

Meanwhile, in the etching process for forming a variable resistance element, an etching byproduct originating from the etching target may be re-deposited on the surface that is being etched. As a result, a second spacer 340 originating from the etching byproduct may be formed on the sidewall of the variable resistance element after the variable resistance element is patterned. However, the etching byproduct originating from the layer that is etched late among the layers of the variable resistance element, that is, the layer disposed in the lower portion, may form a large proportion of the spacer 340, and the etching byproduct originating from the layer that is etched early among the layers of the variable resistance element, that is, the layer disposed in the upper portion, may be scarcely contained in the spacer 340 (for example, form a small or minimal proportion of the spacer 340). This is because the etching byproduct that is re-deposited in the middle of the etching process is mostly removed again as the etching proceeds. The second spacer 340 may be disposed over at least a portion of the sidewall of the MTJ pattern 320A and may include carbon, aluminum oxide, titanium oxide, or tantalum oxide.

Referring to FIG. 3C, the MTJ etching byproduct 330 may be removed together with the sacrificial layer 315. The sacrificial layer 315 may be a layer that is designed to be removed together with the MTJ etching byproduct 330, and a dry etching process or a plasma etching process may be performed to remove the sacrificial layer 315. Since the sacrificial layer 315 is formed of a material having an etching selectivity with respect to the hard mask pattern 329A, only the sacrificial layer 315 and the MTJ etching byproduct 330 accumulated over the sacrificial layer 315 may be selectively removed without damaging the MTJ pattern 320A including the capping layer pattern 328A, the magnetic compensation layer pattern 327A, the exchange bonding layer pattern 326A, the fixed layer pattern 325A, the tunnel barrier layer pattern 324A and the free layer pattern 323A during the etching process of the sacrificial layer 315.

Most of the sacrificial layer 315 may be removed by a dry etching process and a wet cleaning process, but a portion of the sacrificial layer 315 may remain to form the sacrificial layer pattern (not shown) over at least a portion of the spacer 322. The sacrificial layer pattern may structurally support the variable resistor element including the MTJ pattern 320A including the capping layer pattern 328A, the magnetic compensation layer pattern 327A, the exchange bonding layer pattern 326A, the fixed layer pattern 325A, the tunnel barrier layer pattern 324A, and the free layer pattern 323A. This supporting function may contribute to maintaining the physical stability of the variable resistor element, particularly after the pattern is formed.

Referring to FIG. 3D, a second inter-layer dielectric layer 335 may be formed over the structure of FIG. 3C. In instances in which the surface of the structure of FIG. 3C is cleaned by a dry etching process and a wet cleaning process, the bonding between the second inter-layer dielectric layer 335 and the surface of the structure of FIG. 3C may be (more easily) facilitated or improved.

A semiconductor device as illustrated in FIG. 3D may be formed by the process described above.

Referring back to FIG. 3D, the semiconductor device in accordance with the embodiment of the present disclosure may include the lower contact plug 310 disposed over the substrate 300 and coupled to a portion of the substrate 300, the first inter-layer dielectric layer 305 filling the space between the lower contact plugs 310, the lower electrode pattern 321 coupled to the lower contact plug 310 over the lower contact plug 310, the spacer 322 formed on a sidewall of the lower electrode pattern 321, the MTJ pattern 320A coupled to the lower electrode pattern 321 over the lower electrode pattern 321, a second inter-layer dielectric layer 335 that covers an exchange bonding layer pattern 326A, the magnetic compensation layer pattern 327A, the capping layer pattern 328A, the hard mask pattern 329A, the first spacer 322, the second spacer 340, and the upper surfaces thereof.

According to the embodiment of the present disclosure, a structure may be formed to include the exchange bonding layer pattern 326A, the magnetic compensation layer pattern 327A, and the capping layer pattern 328A further stacked over the MTJ pattern 320A, and include the second spacer 340 further formed on the sidewall of the variable resistance element. In accordance with the embodiment of the present disclosure, all the advantages described in the above-described embodiment of the present disclosure may be obtained as well. For example, MTJ etching byproduct 330 may be effectively removed to prevent deterioration of the magnetoresistance characteristics of the MTJ element and the reliability of the MTJ element and prevent deterioration of the performance of inter-layer insulation and the electrical characteristics of the MTJ element. Additionally, the sacrificial layer pattern may structurally support the MTJ pattern 320A and contribute to maintaining the physical stability of the MTJ pattern 320A.

According to the embodiment of the present disclosure, the semiconductor device and the method for fabricating the same may prevent malfunction of an MTJ element and significantly improve the performance and reliability of the MTJ element by effectively solving the problem of the byproduct generated after an MTJ etching process being accumulated between the electrodes and serving as a bridge source.

While the present disclosure has been described with respect to the specific embodiments, it will be apparent to those skilled in the art that various changes and modifications may be made without departing from the spirit and scope of the invention as defined in the following claims.

What is claimed is:

1. A semiconductor device, comprising:
a semiconductor memory,
wherein the semiconductor memory includes at least one stacked structure, wherein each of the at least one stacked structure includes:
an electrode pattern;
a magnetic tunnel junction (MTJ) pattern formed over the electrode pattern;
a hard mask pattern formed over the MTJ pattern;
a first spacer formed on both sidewalls of the electrode pattern; and
a sacrificial layer pattern formed over at least a portion of the first spacer and supporting the MTJ pattern and the hard mask pattern.

2. The semiconductor device of claim 1, wherein the sacrificial layer pattern includes carbon.

3. The semiconductor device of claim 2, wherein the sacrificial layer pattern further includes
polysilicon, silicon oxide, silicon nitride, aluminum oxide, or titanium oxide.

4. The semiconductor device of claim 1, wherein the first spacer includes
silicon oxide, silicon nitride, hafnium oxide, tantalum oxide, tantalum nitride, titanium nitride, aluminum oxide, or a combination thereof.

5. The semiconductor device of claim 1, wherein the semiconductor memory further includes
an inter-layer dielectric layer suitable for covering the MTJ pattern, the hard mask pattern, and at least a portion of the first spacer.

6. The semiconductor device of claim 5, wherein the inter-layer dielectric layer includes silicon oxide, silicon nitride, silicon oxynitride, silicon oxide carbonitride, or a combination thereof.

7. The semiconductor device of claim 1, wherein the MTJ pattern includes:
a free layer pattern having a changeable magnetization direction,
a fixed layer pattern having a fixed magnetization direction, and
a tunnel barrier layer pattern interposed between the free layer pattern and the fixed layer pattern.

8. The semiconductor device of claim 7, further comprising:
a magnetic compensation layer pattern configured to at least partially offset an influence of a stray magnetic field that is generated by the fixed layer pattern over the fixed layer pattern.

9. The semiconductor device of claim 1, further comprising:
a second spacer disposed over at least a portion of a sidewall of the MTJ pattern and including carbon, aluminum oxide, titanium oxide, or tantalum oxide.

10. The semiconductor device of claim 1, wherein the electrode pattern includes
an upper portion having an upper portion sidewall aligned with the MTJ pattern, and
a lower portion having a lower portion sidewall, wherein the lower portion sidewall is not aligned with the upper portion and a width greater than a width of the upper portion.

11. The semiconductor device of claim 1, wherein the hard mask pattern includes a dielectric material selected from a group including silicon oxide, silicon nitride, silicon carbide, aluminum oxide, hafnium oxide, titanium oxide, and zirconium oxide.

12. A method for fabricating a semiconductor device, comprising:
forming a magnetic tunnel junction (MTJ) layer over a sacrificial layer having an electrode pattern buried therein;
forming a hard mask layer over the MTJ layer;
forming an MTJ pattern and a hard mask pattern by etching the MTJ layer and the hard mask layer, where an etching byproduct of the MTJ layer is accumulated on an upper surface of the sacrificial layer;
removing the etching byproduct while removing the sacrificial layer.

13. The method of claim 12, wherein the sacrificial layer includes carbon.

14. The method of claim 13, wherein the sacrificial layer further includes polysilicon, silicon oxide, silicon nitride, aluminum oxide, or titanium oxide.

15. The method of claim 12, wherein the etching of the MTJ layer is performed by an ion beam etching (IBE) process.

16. The method of claim 12, wherein the forming of the MTJ layer includes sequentially forming a free layer, a tunnel barrier layer, and a fixed layer, and
the forming of the MTJ pattern includes forming a free layer pattern, a tunnel barrier layer pattern, and a fixed layer pattern.

17. The method of claim 16, further comprising:
forming a magnetic compensation layer between the MTJ layer and the hard mask layer, and
forming a magnetic compensation layer pattern configured to at least partially offset an influence of a stray magnetic field generated by the fixed layer pattern between the MTJ pattern and the hard mask pattern by etching the magnetic compensation layer.

18. The method of claim 12, wherein the forming of the MTJ pattern by etching the MTJ layer includes,
forming a second spacer including carbon, aluminum oxide, titanium oxide, or tantalum oxide over at least a portion of a sidewall of the MTJ pattern.

19. The method of claim 12, wherein the hard mask layer includes a dielectric material selected from a group including silicon oxide, silicon nitride, silicon carbide, aluminum oxide, hafnium oxide, titanium oxide, and zirconium oxide.

20. The method of claim 12, further comprising:
after the removing of the sacrificial layer and the etching byproduct, forming an inter-layer dielectric layer that covers the MTJ pattern and at least a portion of the hard mask pattern.
